(19) United States
(12) Patent Application Publication
(10) Pub. No.: US 2016/0035259 A1
(43) Pub. Date: Feb. 4, 2016

(54) Volumetric Three-Dimensional Display with Evenly-Spaced Elements

(71) Applicant: Thomas BRINDISI, (US)

(72) Inventor: Thomas J. Brindisi, Key West, FL (US)

(21) Appl. No.: 14/777,455

(22) PCT Filed: Mar. 15, 2014
(86) PCT No.: PCT/US14/29922

§ 371 Date: Sep. 15, 2015

Related U.S. Application Data
(60) Provisional application No. 61/801,437, filed on Mar. 15, 2013.

(51) Int. Cl. G09G 3/00; G02B 27/22; G06T 15/08; G09G 3/32; G06T 11/00

(52) U.S. Cl. CPC G09G 3/003; G09G 3/3208; G06T 11/008; G06T 15/08; G02B 27/2278; G09G 2300/0452; G06T 2200/04

(57) ABSTRACT

A volumetric three-dimensional light-emitting display, comprising an array of emitters arranged, as defined by the relative positions of the emitters' centerpoints, in a close-packed relationship; and an array of conductors in electrical contact with the array of emitters. The array of emitters may for example comprise conventional RGB stacks or similar full-color assemblages or four different-colored emitters.

### CROSS-REFERENCE TO RELATED PATENT APPLICATION

This application claims benefit of the priority of U.S. provisional patent application Ser. No. 61/801,437 filed with the same title on Mar. 15, 2013, and incorporates by reference the contents of said application.

### FIELD OF THE INVENTION

The present invention relates to three-dimensional displays, and in particular to volumetric, three-dimensional displays.

### BACKGROUND

It is believed that hitherto, the obvious, realistically useful way to lay out a three-dimensional display comprising light emitting diodes has been to utilize identical layers (e.g., a two-dimensional OLED display) that repeat directly upwardly in the z axis, one atop the next. This has been done at least since U.S. Pat. No. 5,929,572 to Whitesell and GB Patent Application 2376555 to Eickhoff, through U.S. Patent Application Publication No. 2004/0145538 to Uchida et al., U.S. Pat. No. 6,720,961 to Tracy, U.S. Patent Application Publication No. 2009/0002266 (now issued as U.S. Pat. No. 8,525,954) to Li et al., and U.S. Pat. No. 7,587,120 to Koo et al.

Work in the LED television and monitor field, though extensive, is ‘pixel-centric’ (and likely moreso with OLED's rise), and conventional two-dimensional pixels arrays are not prone to being stacked to create a three-dimensional volumetric display in any arrangement other than identical, direct stacks. Further, it is believed that where those in the field have deliberately controlled the relative distancing of layers from one another in stacked volumetric displays (e.g., DE 2008007287), it has been for purposes other than (and not consistent with) establishing a three-dimensionally regular voxel or a three-dimensionally even element spacing.

Even if one in the field had contemplated trying to depart from the existing model, and if they happened to consider the notion of space-filling in the process, the possibility of employing an arrangement of elements that is derived from the geometry of the close-packing of spheres would not have appeared to be a good candidate. For one thing, a spherical voxel would be impractical to construct. (A voxel might be formed of a spherical-shaped diffusing material, but the opacity of the resulting extent of diffusing material is not desirable for a volumetric three-dimensional display, if not untenable depending on the density and depth of elements). In any case, when densely-packed, spheres leave numerous gaps of two different shapes and only fill about 74% of space; similarly with the regular tetrahedrons that are formed by connecting the centerpoints of close-packed spheres. Further, the standard group of emitters used to generate full color (e.g., 256+colors) LED displays comprises three emitters (red, green, and blue, or RGB), with other groups that consist of more or less than three emitters now receiving comparatively little (and often diminishing) attention; if a space-filling approach would have been entertained hitherto, the approach would also have been repelled by the lack of advantage to laying out R, G, and B emitters in a three-dimensional pattern.

### SUMMARY OF THE INVENTION

Despite the fact that regular tetrahedral structures cannot fully tessellate a volume, Applicant has found that by utilizing a close-packed lattice arrangement of elements in a novel volumetric three-dimensional display, certain key functional advantages can be derived that generate meaningfully enhanced performance. Utilizing four different-colored emitters in this arrangement permits a scheme wherein a smooth and uniform flow of voxels and boundaries that is impossible in the conventional arrangement can be achieved. Using a conventional RGB emitter stack (or similar full-color assemblage) for each of the elements in a close-packed lattice can provide related unique benefits.

### BRIEF DESCRIPTION OF THE DRAWINGS

FIG. 1 is a partial perspective view illustrating the structural and functional arrangement of an embodiment of the invention that is arranged in a face-centered cubic array with a three-dimensional arrangement of four sets of differently-colored emitters.

FIGS. 2A-5B are sectional views of an embodiment that is based on FIG. 1 but further includes an encapsulant, wherein:

FIG. 2A shows a plane that is parallel to the one that generally appears as the top face of the roughly cube-shaped array of FIG. 1, the depicted plane being like one indicated in FIG. 1 with the set of dashed lines indicated by RG;

FIG. 2B shows a plane that is parallel to the plane of FIG. 2A, the depicted plane being like one indicated in FIG. 1 with the set of dashed lines indicated by BY;

FIG. 3A shows a plane that is parallel to the one that generally appears as the left front face in FIG. 1, the depicted plane being like one indicated in FIG. 1 with the set of dashed lines indicated by RY;

FIG. 3B shows a plane that is parallel to the plane of FIG. 3A and is like one indicated with the set of dashed lines indicated by GB in FIG. 1;

FIG. 4A shows a plane that is parallel to the one that generally appears as the right front face in FIG. 1, and which is indicated with the set of dashed lines indicated by GY in FIG. 1;

FIG. 4B shows a plane that is parallel to the plane of FIG. 4A and is like one indicated with the set of dashed lines indicated by RB in FIG. 1;

FIG. 5A shows a plane of a type that is found between the planes depicted in FIGS. 3A & 3B; and

FIG. 5B shows a plane of a type that is found between the planes depicted in FIGS. 2A & 2B, and is found between the planes depicted in FIGS. 4A & 4B.

### DETAILED DESCRIPTION OF EMBODIMENTS

The figures depict a portion of a volumetric display 100 having a basic face-centered cubic arrangement of emitters 101-104 (which typically comprise the layers [such layers not depicted here] of a conventional inorganic or organic light emitting diode) including red emitters 101, green emitters 102, blue emitters 103, and yellow emitters 104. The structure is arranged so that there are repeating identically-oriented, evenly-spaced, regular tetrahedral shaped voxels comprising one of each emitter. (The tetrahedrons' edges are defined by imaginary lines connecting the emitters' centerpoints. “Centerpoint” as used herein generally just means the geometric three-dimensional center of the emitter structure, but for some emitters the source of light emission may be sufficiently separate from the geometric center as to behoove a mathematical assessment of the position of the center of the source as opposed to an overall diode feature or the like). The conductors 110 and 111 are preferably transparent, and there is preferably a transparent, electrically-insulating encapsulant 108. (As used herein, “encapsulant” does not imply any specific method of manufacture whatsoever, and merely refers to the structural relationship between the encapsulant and other parts of the display).

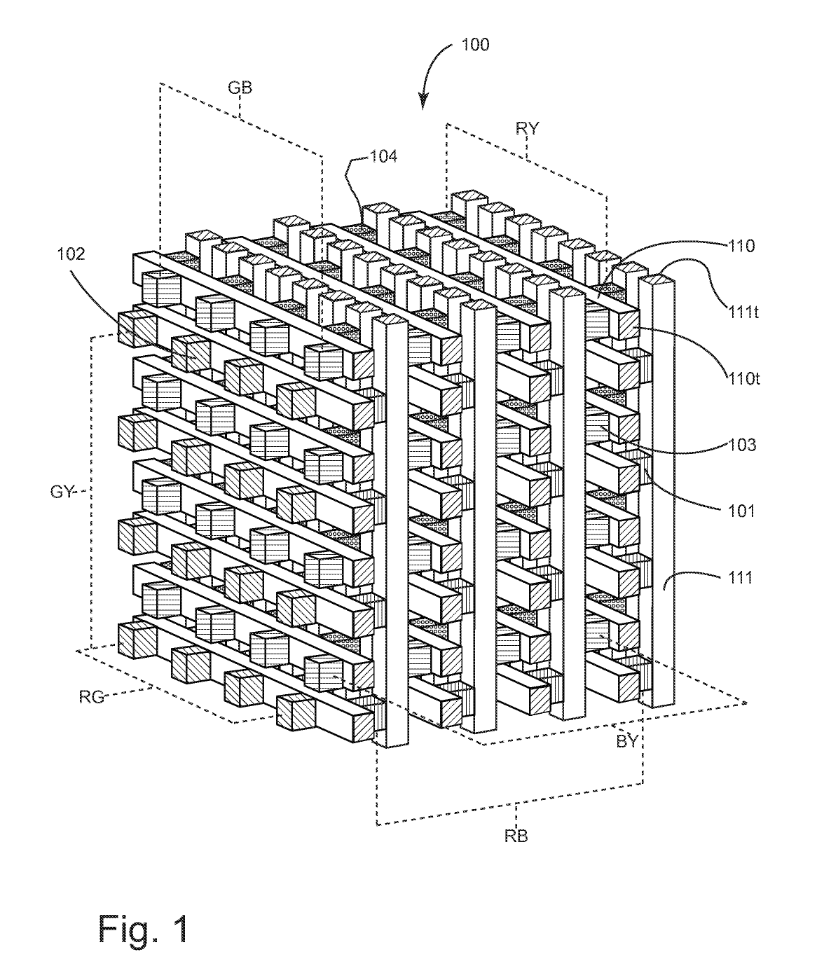

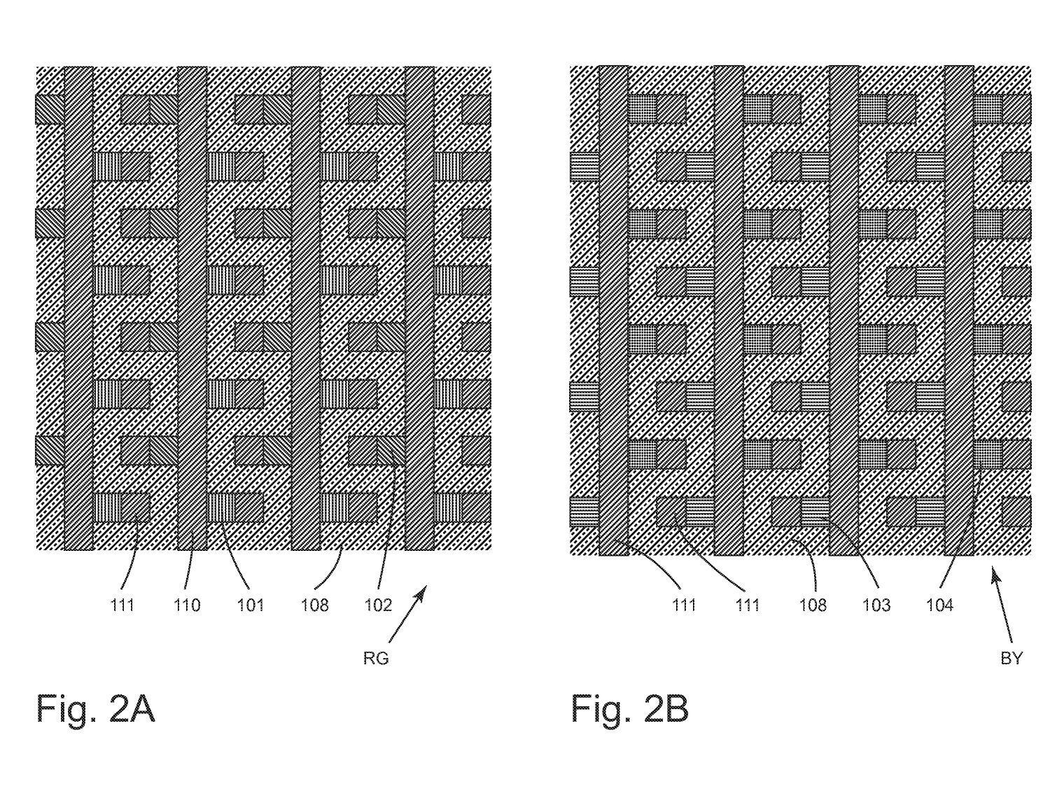

The conductor tips 110t are preferably permanently affixed to a side plate (not shown) that is aligned with the front right face of array of FIG. 1, and likewise with conductor tips 111t as to the top face. Sturdy design would be relatively more required of detachable side plates, but an economical version would be feasible if the side plates employ an array of X by Z, X by Y or Y by Z drive connection elements (where X, Y, and

Z are the number of conductor tips in the corresponding columns or rows) that only or primarily consist of conventional wires and metal, adapted to connect to a controller connector on one side (e.g., with a X+Z or X+Y or Z+Y pin connector) and on their other side provided with contact pads or engagement features (e.g., flat, brushed, pointed, etc.) to engage and connect to the conductor tips. Alternately, the side plates could include a transparent, e.g., injection-molded mezzanine-style header that routes and narrows the leads down to a compact opaque cable. In either case, the side plates may permit connection to a conventional interface (e.g., HDMI), preferably either with a chip and/or firmware or software onboard (and suitable content delivered from the other side of the connection) to derive a useable signal.

A small-sized but high element-density embodiment can be adapted for compatibility with a mobile device capable of delivering volumetric three-dimensional content or otherwise usefully interacting with the display. In toy or artistic display embodiments, the display may preferably be powered with a rechargeable onboard battery such as a Li-ion battery pack, with the base of the device being appended to one of the side plates, and containing circuitry to permit it to display visually-interesting three-dimensional patterns stored in an onboard memory and/or delivered wirelessly by communication another device (e.g., through incorporation of a Bluetooth or Wi-Fi transceiver in the base).

In a face-centered cubic embodiment in which conductors 110 and 111 are laid out as depicted in the figures (with the planes of the associated sectional views containing only two colors of emitters each), if d is the distance between the center-points of each closest element to the next, the depicted planes of elements (where they intersect the elements' centerpoints) are pitched √1/2d apart with the centerpoints of adjacent planes' elements staggered by √2/2d. In an embodiment with the emitters' centerpoints arranged at the same positions as depicted in the figures, but with the conductors etc. instead laid parallel to the regular hexagonal grid-shaped planes that contain all four colors (these are the repeating “A/B/C” planes of the face-centered cubic pattern), then the emitter planes are pitched √2/3d apart and each is identical except shifted by (√3/4+29 1/12)d vis-à-vis the plane above or below. In the latter embodiment, rather than having two sets of conductors that are arrayed at 90° angles to each other as depicted, there may be two sets of conductors arrayed at 120° angles to each other (although if the emitters are small enough relative to the insulating encapsulant 108, they alternately also could be wired at 90° angles). Such a wiring would naturally produce a somewhat unfamiliar ‘open-book’ shaped arrangement, which in most embodiments will enhance the display's multi-directional viewability.

The close-packed lattice/tetrahedral voxel arrangement enables meaningful enhancements in the depiction of motion, points, edges, and boundaries. When used with a four color emitter group, arranged by color as depicted in the figures, the tetrahedral voxel of such an arrangement can be moved up, down, left, right, back or forth in equal distances, but every such voxel also consists of two pairs of emitters each of which can form part of that voxel or another voxel. Consequently, the display can be driven (and the wiring arranged to facilitate) to move the element depicted by voxel “1” a fraction of a voxel away to occupy a voxel that occupies two of the emitters of original voxel “1.” This can be done on a continual basis, preferably with the associated logic and computations performed by a suitable graphics processor, and permitting fidelity of motion not attainable otherwise. Similarly, every emitter can form part of eight different tetrahedral voxels; thus for example a voxel could swing or wheel through eight different and equally-close positions that all occupy the same emitter.

Another embodiment of the invention utilizes a generally conventional RGB (or other full-color producing) vertically-stacked emitter (see e.g., U.S. Patent Application Publication No. 2009/0078955 to Fan et al., which is incorporated herein by reference) as the close-packed elements. In this case, although as noted the space is not optimally filled, every emitter is surrounded by twelve other emitters that are equally close—a set of four spaced apart 90° from each other in each of three mutually-orthogonal planes. This means that for a given voxel depicting a moving element (of specified variable color) at a point in time, there will be twelve evenly-distributed available directions in which the depicted element can proceed to, and whichever way it moves, the new voxel depicting the element will likewise have direct freedom of motion in twelve directions. Because a simple cubic array permits only six direct degrees of freedom, the present embodiment makes possible an improved smoothness of displayed motion. This embodiment of course requires more intricate patterning to connect all four electrodes of each emitter stack to the corresponding conductors.

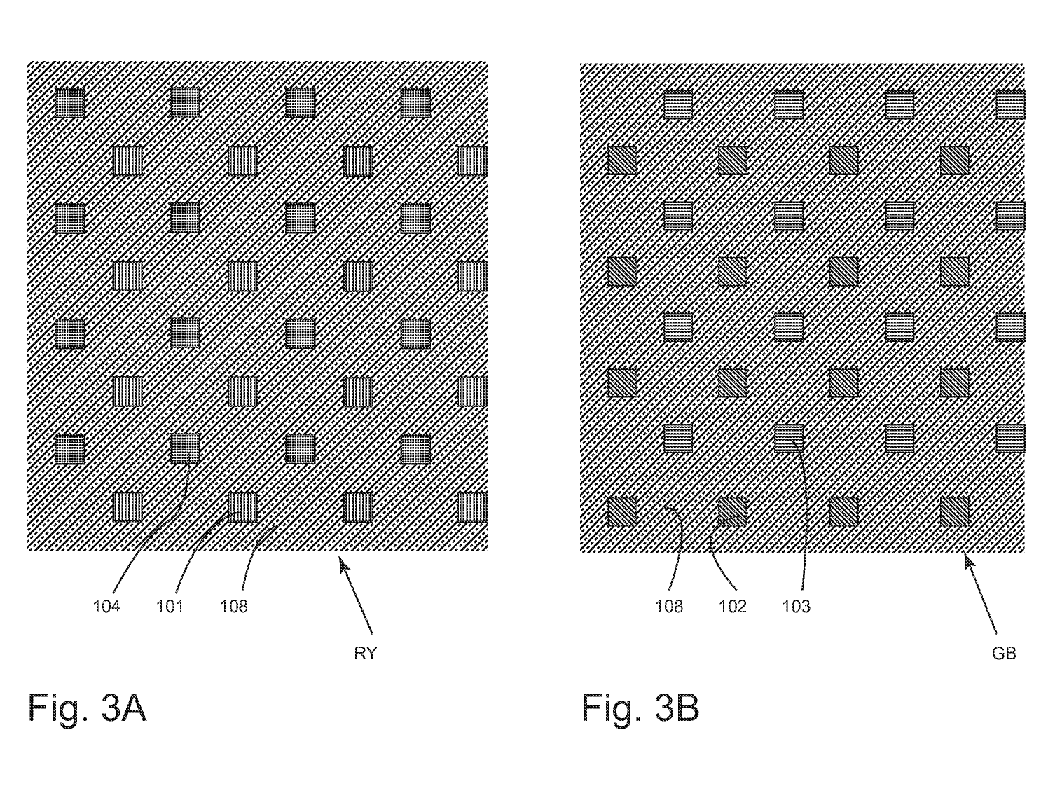

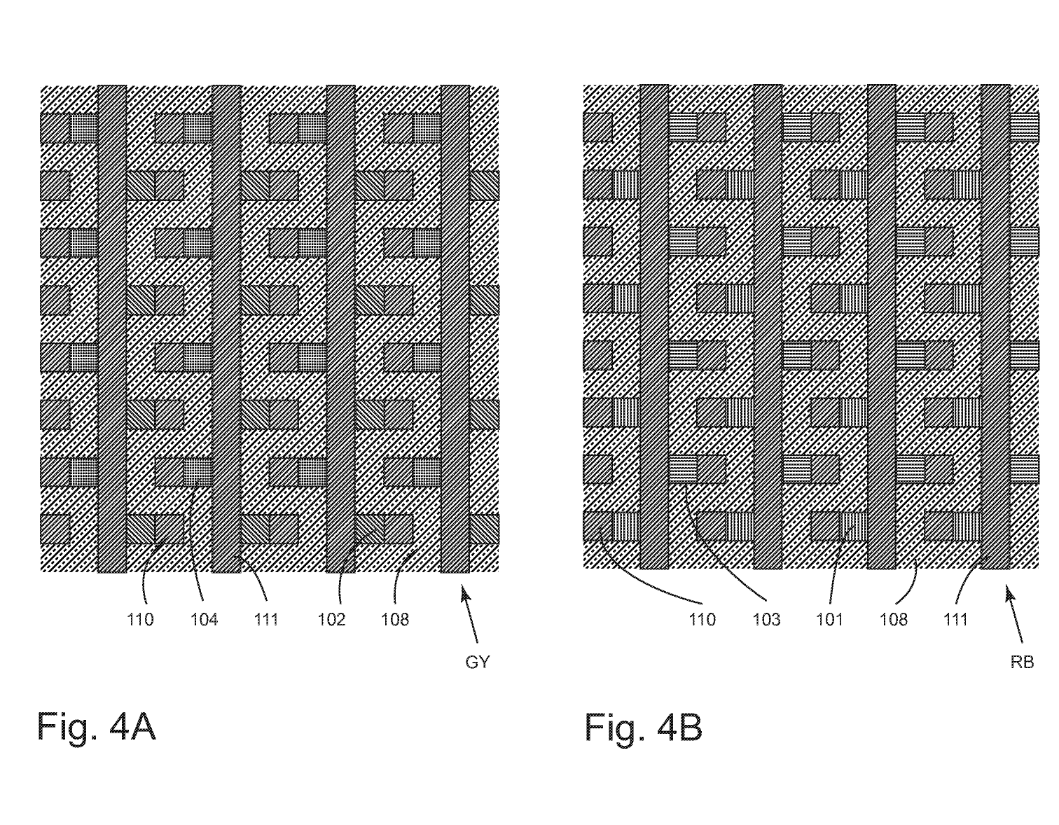

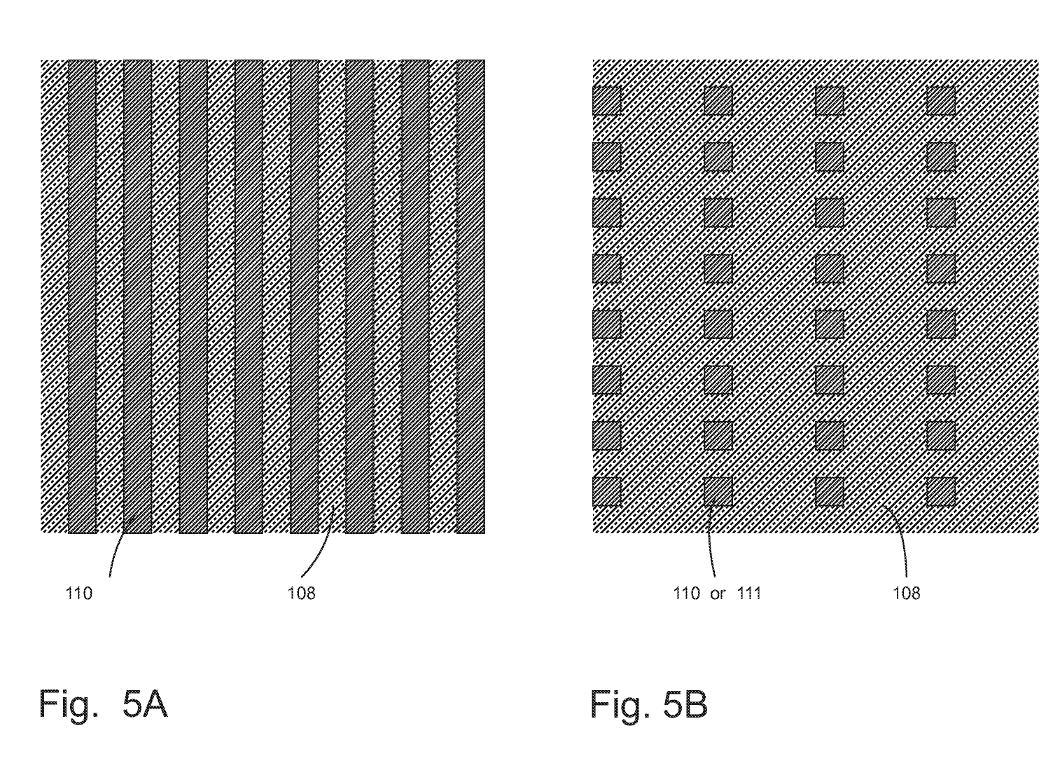

Centerpoints are the basis of measurements discussed here, and the relative sizing of the emitters, insulators, and conductors with respect to each other can be varied over significant ranges. The invention can be implemented using a variety of methods and at widely varying scales. A large (e.g., designed for outdoor or other distant viewing) embodiment may have a d of multiple millimeters or even centimeters and use high-powered (e.g., inorganic) emitters, while an embodiment utilizing transparent OLED materials can be made with a pitch of fractions of a millimeter. As will be appreciated from the patterns of emitters and conductors illustrated in FIGS. 3A, 3B, and 5A, at least in the wiring arrangement depicted, the invention is amenable to transparent OLED manufacturing techniques including those based on solution processing, spin or slot die coating, deposition and/or removal (sputtering, chemical, laser, UV, etc.), printing, micro-imprinting, etc., and combinations and hybrids thereof. The teachings of U.S. Patent Application Publication No. 2007/0126354 to Chao, U.S. Patent Application Publication No. 2010/0308353 to Grabowski et al., and Cho et al., Highly transparent organic light-emitting diodes with a metallic top electrode: the dual role of a Cs₂CO₃ layer, Optics Express 19:2, pages 1113-21 in that regard are incorporated herein by reference.

Layers are serially produced atop each other in the planes of the figures just noted, with spacing and layer heights as mathematically dictated above and overseen through manufacturing controls pertinent to a given process, with the conductors and emitters being surrounded by insulator 108. Conventional means are readily available to laterally align the layers in the aforementioned processes precisely; for example in a mask process, registration (see, e.g., Guizar-Sicairos, Efficient subpixel image registration algorithms, Optics Letters 33:2 (2008), which is incorporated herein by reference), and if necessary for a high resolution embodiment metrology, pattern recognition and/or other techniques can be employed. Likewise, certain manufacturing steps may call for conventional enhancements and adjuncts to ensure a consistent height of the portion being made. Rather than three-dimensionally thick, monolithic conductors 110/111 as depicted in the figures, in place of each conductor, two parallel thin conductor layers can be provided (not shown)—one contacting the line of emitters on one side (of the replaced conductor) and the other contacting the emitters on the other side—with encapsulant occupying the region between the conductor layers.

The display is preferably produced as an integral, monolithic solid part (although an embodiment could be made that entraps regions of fluid such as liquid crystal, without departing from the invention) that is substantially transparent when not energized, does not contain gas, and has materials and relative sizes chosen to mitigate transmission loss, reflection and refraction at layers (including due to birefringence), and to optimize the mixing of each voxel's light. “Substantially transparent” and the like intend that a material (based on its respective portion of the total transmission loss that includes contributions from the other materials that comprise an average applicable layer) passes usefully-visible (for the purpose of a display) light from its elements through multiple (at least eight) layers of the embodiment at issue. The insulator 108 preferably comprises PMMA, but it can also comprise polycarbonate or other polymers compatible with the chosen emitter makeup, conductor material, manufacturing methods, and intended use. Layouts that would incur cross-talk are to be avoided, as are configurations (including film thicknesses, etc.) that would create destructive or constructive thin film interference or diffraction; optically-enhancing, e.g., anti-reflective layers also may be applied.

Commercially dominant transparent conductor materials may be used, or performance can be increased by utilizing materials that have superior properties and are more convenient to process, such as nano-silver (e.g., Cambrios' ClearOhm® and U.S. Pat. No. 8,018,568 to Allemand et al., KeChuang's AW030; and see also Chung et al, Solution-Processed Flexible Transparent Conductors Composed of Silver Nanowire Networks Embedded in Indium Tin Oxide Nanoparticle Matrices, Nano Res, (Springer 2012), Zeng et al., A New Transparent Conductor: Silver Nanowire Film Buried at the Surface of a Transparent Polymer, Advanced Materials 22:4484-85 (Wiley 2010), Hu et al., Scalable Coating and Properties of Transparent, Flexible, Silver Nanowire Electrodes, ACS Nano 4:5, pages 2955-63 (2010), U.S. Patent Application Publication No. 2011/0094651 to Kuriki, and Spechler et al., Direct-write pulsed laser processed silver nanowire networks for transparent conducting electrodes, Applied

Physics A (Springer 2012), each of which is incorporated herein by reference), carbon nanotubes (see e.g., Hecht et al., Transparent conductive carbon-nanotube films directly coated onto flexible and rigid polycarbonate, J. Soc. Info Display 19:2, pages 157-62 (2011), which is incorporated herein by reference), and graphene (see e.g., Moon et al., 2D Graphene Oxide Nanosheets as an Adhesive Over-Coating Layer for Flexible Transparent Conductive Electrodes, Scientific Reports 3:1112 (2013), which is incorporated here by reference).

In most embodiments, the choice of encapsulant and conductor material(s) will in part limit each other or dictate additional steps such as refraction index tuning, anti-reflective layers, optical bonding or laminating, etc. The refractive index of each should be matched well to the other (and tuned if desirable—see e.g., Hanemann, Tuning the polymer [ ] index with nanosized organic dopants, which is incorporated herein by reference). PMMA's index is fairly close to PEDOT:PSS and some embodiments of nanosilver and carbon nanotubes solutions. To the extent that birefringent materials are used, steps may be taken to mitigate the effects of that, including optimizing anisotropic orientations and possibly the addition of a negatively-birefringent film. A glass-encapsulated embodiment may utilize a high refraction index glass chosen to better match ITO or the like, in which case optical bonding may also be employed, as can lamination in the case of an OLED/polymer embodiment.

A wide range of emitter types are suitable, including inorganic LEDs, OLED, hybrid LED/OLED structures, nanowire LED (see e.g., U.S. Pat. No. 8,129,701 to Cho et al.), and others. The emitters in most embodiments should be of a form, shape, and materials selected for a low angular spectral dependence, particularly in the preferred embodiments wherein the array has a significant depth (meaning eight or more layers) and the display is intended for viewing over a broad range of angles. One embodiment utilizes OLED emitters and compatible transparent materials, but has two dimensions that are significantly greater than the third, which comprises at least eight RGBY layers, preferably one or a few dozen. Such an embodiment can be rendered like a three-dimensional, volumetric ‘fish-tank’ style display that a user can view up close to see a number of individual objects being depicted, with sharpness and smoothness of motion that is enhanced over conventional and prior art stacked OLED displays.

Though numerous well-known processes can be used depending on the embodiment, some embodiments would also be amenable to somewhat unconventional processes. For example, an array of pre-formed polymer (or glass) rectangular-profiled rods (preferably with embedded or attached emitters) could be assembled in registration and pressed together and heated, either all at once, or layer-by-layer, hermetically encapsulated under vacuum; such rods could be manufactured from flat layers of insulator coated on their surfaces with the relevant conductor materials (such as with the nanoAG method used by Chung et al., supra, which may reduce the effects of refraction index changes) and then e.g., laser-cut into strips. As another example, an embodiment may be produced in part by molding and then joining sheets like those of FIGS. 3A, 3B and 5A (preferably with two layers of film used as conductors in place of each of the ones depicted).

Subvoxel mixing of perceived colors could be enhanced structurally by selecting and configuring emitters to have maximally overlapping étendues, and employing techniques appropriate to a given embodiment such as light guiding, diffusing, or in the case of directional (e.g., side-emitting) emitters, mutual reflection between two emitters (such as the two pairs that comprise a tetrahedral voxel in the depicted embodiment). A possible hybrid LED embodiment could include very small, low-power inorganic LEDs, with variable conductivity leads that gradually get wider and less conductive toward a larger transparent conductor contact area. Small inorganic LEDs arranged in the face-centered cubic lattice could include side-emitting LEDs (with or without Lambertian or OLED-profile emitters also in a given voxel) and might lend themselves to electrochromic mixing.

A display made according to the invention also is favorably amenable to multiple wiring methods, many including lines of a single color emitter (such as in the figures if the conductors are replaced with two opposing film layers as described above) so as to facilitate driving schemes that benefit from physically-divided color channels. As noted, multiple 90° or 120° orientations (and their corresponding device shapes) can be employed. The wiring also can be done to multiplex (using pulse width modulation) the emitters of an embodiment such as that depicted in the figures, though in some embodiments the extent of this option is limited by the capacity of the conductor material (or other performance related issue such as cross-talk in an overly-dense layout) before noticeable boundaries of the persistence of vision effect are passed. In some embodiments, such as a small 8×8×4 or 8×8×8 toy or a like- or moderately greater-number of voxel visual art display embodiment, the display may not have enough voxels to render realistic content but still can generate a smoother flow of light and patterns for the reasons described herein. The persistence of vision (“p.o.v.”) effect can also be exploited for enhanced perceived movement vis-a-vis the p.o.v. effect in a display without the arrangements described herein. The use of four-color emitter groups creates a design choice in driving the emitters to depict the color space, as there is not a unique solution (of relative light intensities, or equivalently pulse width modulation values) for a given desired light frequency as with three-color groups. Various current makers of commercial products utilize RGBY (or RGBA (to be distinguished from RGBa)) to do so, including Sharp (Acquos®) and Norlux Corp. of Illinois (a provider of to-spec LED lighting drive circuitry including for RGBY), and others. A somewhat generic solution to four-element programming could include calculating an RGB set of values, an RBY set of values, RGY, and GBY, and averaging or interpolating them for a single RGBY value; also, a plethora of visually-distinct and entertaining solutions (preferably accentuated by smooth voxel motion) for a toy or artistic visual display embodiment could be easily devised by one of ordinary skill.

Diverse embodiments of the present invention are likely to be further enhanced by means of Bright Pupil or Dark Pupil eye-tracking to locate the position of the viewer relative to the array, and employ a processor (onboard, in a graphics processor assembly, etc.) to provide an even, controlled effective display to the user over time and at different viewpoints, drive the units that are ‘rearward’ from the user's perspective with higher power and/or different driving characteristics so as to normalize the elements' output with respect to each other based on their currently expected relative light loss. This effect also can be applied, depending on the configuration, to normalize elements' perceived output through changing relative alignment of the user's position and the emitter's étendue, and to modify output color to offset any angular spectral dependence and/or wavelength-dependent differential rate of loss of the emitters' visible output through the materials used. There is a non-close-packed structure and arrangement that repeats in three dimensions regularly and symmetrically, namely a simple cubic arrangement (as defined by the relative positions of the emitters' centerpoints) with each cube-shaped voxel comprising eight emitters, either as eight different colored emitters or as four pairs of like colors wherein each emitter in a voxel is placed at the farthest opposite corner from its like color. A simple cubic lattice thus organized and repeated identically in the x, y, and z axes may be useful in contexts or applications in which the emitter density associated with having eight fully spaced-apart emitters per single voxel is not an undue hindrance, and where it is desired to selectively control directional light output of a volumetric three-dimensional display. In this embodiment, the display could be adapted to provide power (or alternately, no power) selectively to subgroups of a voxel's emitters, which could for example be grouped so that in odd layers the emitters are oriented in one direction and in even layers they are oriented in another. It could also further be adapted to perform eye-tracking, and selectively provide power to emitters based on a location of a user as ascertained thereby. Alternately, the selective control of power could be linked to input from a gyroscope, a touch or pressure-sensitive element, a motion- and/or light-detector, or any other perceivable source of information that may be relevant to the desirable output direction of the display.

The embodiments discussed herein have assumed the practical desirability of passive addressing to avoid the intervening layers of active electronics such as TFT, however, it is believed that (at least for smaller arrays) such can be implemented reasonably well even with existing transparent TFT. These and other readily apparent implementations and modifications are within the scope of the invention; unless indicated, the particulars of preferred embodiments described above are not meant as limitations on the following claims.

1-9. (canceled)

10. A three-dimensional light-emitting display comprising:
a) a first planar array of regularly-spaced repeating elements, and a second planar array of regularly-spaced repeating elements, wherein the centerpoints of closest-adjacent elements within a planar array are spaced apart from each other by a distance d, and wherein each element's centerpoint is defined by the position of the element's source of visible light; wherein the second planar array is parallel to the first planar array and is pitched apart from the first planar array by a distance that is a first function of d, and wherein the centerpoints of the elements of the first planar array are staggered apart from the centerpoints of elements in the second planar array by a lateral distance that is a second function of d;
b) an array of electrical conductors comprising a first set of electrical conductors arranged so that each element of the first planar array is in electrical contact with exactly two electrical conductors of the first set of electrical conductors configured to energize it, and a second set of electrical conductors arranged so that each element of the second planar array is in electrical contact with exactly two electrical conductors of the second set of electrical conductors configured to energize it;
c) wherein the first and second planar arrays together define a plurality of regularly-spaced voxels each including four elements and capable of generating full color, and wherein either:
i) the elements of each planar array are arranged orthogonally within each planar array, the elements of the first planar array consist of exactly two colors of elements, the elements of the second planar array consist of two different elements that are each different from the elements of the first planar array, and the second function of d is d√2/2; or
ii) the elements of each planar array are arranged hexagonally within each planar array, the elements of the first planar array consist of four different elements, the second planar array is substantially identical to the first planar array, and the second function of d defined by closest like elements is d(√3/4+·1/2); or
iii) the elements of each planar array are arranged orthogonally within each planar array, the elements of the first planar array consist of four different elements, the second planar array is substantially identical to the first planar array, and the second function of d defined by closest like elements is d√2/2.

11-29. (canceled)

30. The display of claim 10, wherein the electrical conductors are substantially transparent.

31. The display of claim 30, wherein at least some of the electrical conductors comprise nano-silver, carbon nanotubes, or graphene.

32. The display of claim 30, further comprising an electrically-insulating material that is substantially transparent, wherein the elements and the electrical conductors are substantially fully encapsulated by the electrically-insulating material.

33. The display of claim 32, wherein the electrically-insulating material is tuned towards the index of refraction of the electrical conductors.

34. The display of claim 33, wherein the index of refraction of the electrically-insulating material and the refraction index profile of the conductors are matched within a value selected from the following group: 5%, 2%, 1%, or 0.5%.

35. The display of claim 32, wherein the elements include light-emitting diodes.

36. The display of claim 32, wherein the light-emitting diodes include organic light-emitting diodes.

37. The display of claim 32, wherein the array of electrical conductors includes electrical conductors that are aligned with and in contact with linear rows of like elements.

38. The display of claim 32, wherein the display is configured to permit electrochromic mixing.

39. The display of claim 10, further comprising a plurality of additional layers each consisting of two planar arrays of elements and two sets of electrical conductors as recited in parts a-c, the layers positioned so that a planar array in each layer is pitched apart from a planar array in an adjacent layer by a distance that is the first function of d.

40. The display of claim 39, wherein the elements define a face-centered cubic lattice.

41. The display of claim 39, wherein the array of electrical conductors includes electrical conductors that are aligned with and in contact with linear rows of like elements.

42. The display of claim 41, wherein the display comprises regularly-repeating layers joined together.

43. The display of claim 39, wherein the elements include light-emitting diodes.

44. The display of claim 39, wherein the display is configured to permit electrochromic mixing.

45. The display of claim 39, wherein either: the elements of each planar array are arranged orthogonally within each planar array and the first function of d is d/√2, or d/2; or the elements of each planar array are arranged hexagonally within each planar array and the first function of d is d√2/3.

46. The display of claim 45, wherein the elements include light-emitting diodes.

47. The display of claim 45, wherein the display is configured to permit electrochromic mixing.

48. The display of claim 45, wherein the array of electrical conductors includes electrical conductors that are aligned with and in contact with linear rows of like elements.
